(19) United States
(12) Patent Application Publication
(10) Pub. No.: US 2026/0305115 A1
(43) Pub. Date: Oct. 1, 2026

(54) ELECTRONIC DEVICE

(71) Applicant: Samsung Display Co., Ltd., Yongin-si (KR)

(72) Inventors: NAMJIN KIM, Yongin-si (KR); WONJANG KI, Yongin-si (KR); YEONJU SEO, Yongin-si (KR); DANBEE SEONG, Yongin-si (KR); SEONG SIK AHN, Yongin-si (KR); HAKBUM CHOI, Yongin-si (KR)

(21) Appl. No.: 19/442,211

(22) Filed: Jan. 7, 2026

(30) Foreign Application Priority Data
Mar. 31, 2025 (KR) 10-2025-0041717

(51) Int. Cl. H10K 59/40; G06F 3/044; H10K 59/122; H10K 59/80; H10K 102/00

(52) U.S. Cl. CPC H10K 59/40; G06F 3/0446; H10K 59/122; H10K 59/873; G06F 2203/04102; H10K 2102/311

(57) ABSTRACT

A display panel of an electronic device includes a base layer including a first region to a third region, an inorganic insulating layer disposed on the base layer, an encapsulation layer including a first inorganic layer disposed on the inorganic insulating layer, a second inorganic layer, and an organic layer disposed between the first and second inorganic layers, and a bank disposed in a peripheral region of the first region and including a first portion and a second portion having a height different from a height of the first portion. An end of each of the first and second inorganic layers disposed in the peripheral region overlaps the first portion and does not overlap the second portion in a plan view, and an end of a sensing insulating layer disposed in the peripheral region overlaps the first portion and the second portion in the plan view.

This application claims priority to Korean Patent Application No. 10-2025-0041717, filed on Mar. 31, 2025, and all the benefits accruing therefrom under 35 U.S.C. § 119, the content of which in its entirety is herein incorporated by reference.

### BACKGROUND

The present disclosure herein relates to an electronic device and more particularly, to an electronic device with reduced permeability of moisture/oxygen in a bending region.

Various display devices used in multimedia devices such as a television, a mobile phone, a tablet computer, a navigation unit and a game console are being developed. Recently, a display panel of which a region is bent and accommodated in a housing is being developed to reduce dead space of a display device. An issue of permeation of moisture/oxygen due to organic layers disposed in a bending region may occur.

### SUMMARY

The present disclosure provides an electronic device which improves an issue of permeation of moisture/oxygen to a bending region.

An embodiment of the invention provides an electronic device including a display panel including an active region and a peripheral region surrounding the active region and an input sensor disposed on the display panel and including a sensing insulating layer and sensing electrodes, where the display panel includes a base layer including a first region including the active region, a second region connected to the first region and bent with respect to a bending axis, and a third region connected to the second region and facing the first region, an inorganic insulating layer disposed on the base layer, pixels disposed in the active region, an encapsulation layer including a first inorganic layer covering the pixels, a second inorganic layer disposed on the first inorganic layer, and an organic layer disposed between the first and second inorganic layers, a dam portion disposed in the peripheral region of the first region and surrounding the active region, and a bank disposed in the peripheral region of the first region adjacent to a boundary between the first region and the second region and including a first portion and a second portion having a height different from a height of the first portion, an end of each of the first and second inorganic layers disposed in the peripheral region overlaps the first portion and does not overlap the second portion in a plan view, and an end of the sensing insulating layer disposed in the peripheral region overlaps the first portion and the second portion in the plan view.

In an embodiment, in the plan view, a width of a separation space between the end of each of the first and second inorganic layers and the second portion may be about 1 micrometer (μm) to about 100 μm.

In an embodiment, an upper surface of the first portion and one side surface of the first portion facing the dam portion may be in contact with the first inorganic layer, and a portion, which is exposed by the first inorganic layer, of the upper surface may be in contact with the sensing insulating layer.

In an embodiment, an upper surface of the second portion and one side surface of the second portion facing the dam portion may be in contact with the sensing insulating layer.

In an embodiment, the first and second inorganic layers may expose a portion of the inorganic insulating layer adjacent to the one side surface of the second portion, and the sensing insulating layer may be in contact with the portion of the inorganic insulating layer.

In an embodiment, a height of the first portion may be greater than a height of the second portion.

In an embodiment, the display panel may further include a first organic insulating layer disposed on the inorganic insulating layer, a second organic insulating layer disposed on the first organic insulating layer, a pixel-defining film disposed on the second organic insulating layer, and a spacer disposed on the pixel-defining film, and the first organic insulating layer, the second organic insulating layer, the pixel-defining film and the spacer may include an organic material.

In an embodiment, the first portion may include first to fourth patterns which are sequentially stacked, and the second portion may include first and second patterns which are sequentially stacked.

In an embodiment, the first pattern of the first portion may include the same material as a material of the first organic insulating layer, the second pattern of the first portion may include the same material as a material of the second organic insulating layer, the third pattern of the first portion may include the same material as a material of the pixel-defining film, and the fourth pattern of the first portion may include the same material as a material of the spacer.

In an embodiment, the first pattern of the second portion may include the same material as a material of the first organic insulating layer, and the second pattern of the second portion may include the same material as a material of the second organic insulating layer.

In an embodiment, the first pattern of the first portion and the first pattern of the second portion may be provided as one connected pattern, and the second pattern of the first portion and the second pattern of the second portion may be provided as one connected pattern.

In an embodiment, the dam portion may include a first dam portion surrounding the active region and a second dam portion surrounding the first dam portion.

In an embodiment, the second dam portion may define a boundary of the organic layer in the peripheral region.

In an embodiment, the first dam portion may include first and second dam patterns which are sequentially stacked, and the second dam portion may include first to third dam patterns which are sequentially stacked.

In an embodiment, the first dam pattern of the first dam portion may include the same material as a material of the pixel-defining film, and the second dam pattern of the first dam portion may include the same material as a material of the spacer.

In an embodiment, the second dam pattern of the second dam portion may include the same material as a material of the pixel-defining film, the third dam pattern of the second dam portion may include the same material as a material of the spacer, and the first dam pattern of the second dam portion may include the same material as a material of the second organic insulating layer.

In an embodiment, side surfaces and an upper surface of each of the first dam portion and the second dam portion may be in contact with the first inorganic layer.

In an embodiment, the inorganic insulating layer may include insulating layers which are sequentially stacked and include an inorganic material.

In an embodiment, the sensing insulating layer may include first and second sensing insulating layers which are sequentially stacked and include an inorganic material.

In an embodiment, a width of the second region may be smaller than a width of the first region.

### BRIEF DESCRIPTION OF THE FIGURES

The accompanying drawings are included to provide a further understanding of the invention, and are incorporated in and constitute a part of this specification. The drawings illustrate embodiments of the invention and, together with the description, serve to explain principles of the invention. In the drawings:

FIG. 1A is a block diagram of an electronic device according to an embodiment;

FIG. 1B is a schematic view of electronic devices according to various embodiments;

FIG. 2A is a perspective view of an electronic device according to an embodiment of the invention;

FIG. 2B is an exploded perspective view of a display device according to an embodiment of the invention;

FIG. 3 is a cross-sectional view taken along I-I′ of FIG. 2B;

FIG. 4 is a cross-sectional view taken along II-II′ of FIG. 2B;

FIG. 5 is a plan view of a display panel according to an embodiment of the invention;

FIG. 6 is a plan view of an input sensor according to an embodiment o the invention;

FIG. 7 is a cross-sectional view of a display module according to an embodiment of the invention;

FIG. 8 is a plan view of a region of a display panel according to an embodiment of the invention;

FIG. 9 is a cross-sectional view taken along III-III′ of FIG. 8;

FIG. 10 is a cross-sectional view taken along IV-IV′ of FIG. 8; and

FIG. 11 is a plan view of a region of a display panel according to an embodiment of the invention.

### DETAILED DESCRIPTION

In this specification, it will be understood that when an element (or a region, a layer, a portion, or the like) is referred to as being “on”, “connected to” or “coupled to” another element, it may be directly disposed on, connected to, or coupled to the other element, or other elements may be disposed therebetween.

Like reference numerals or symbols refer to like elements throughout. In the drawings, the thickness, ratio, and size of the elements are exaggerated for effectively describing the technical contents. As used herein, the term “and/or” includes any and all combinations of one or more of the associated listed elements.

It will be understood that, although the terms “first”, “second”, etc. may be used herein to describe various elements, the elements are not to be limited by these terms. These terms are only used to distinguish one element from another element. For instance, a first element discussed below could be termed a second element without departing from the scope of the invention. Similarly, a second element could be termed a first element. In this specification, the singular expressions “a”, “an” and “the” are intended to include the plural forms as well, unless the context clearly indicates otherwise.

In addition, the terms “below”, “under”, “on the lower side”, “above”, “over”, “on the upper side”, or the like may be used to describe the relationships between the elements illustrated in the drawings. These terms are relative concepts and are described based on the directions indicated in the drawings.

It will be further understood that the terms “comprises, includes, has” and/or “comprising, including, having”, when used in this specification, specify the presence of stated features, numbers, steps, operations, elements, components or combinations thereof, but do not preclude the possibility of the presence or addition of one or more other features, numbers, steps, operations, elements, components, and/or combinations thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

“About” or “substantially equal” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially equal” can mean within one or more standard deviations, or within ±10%, 5% or 2% of the stated value. Hereinafter, embodiments of the invention are described with reference to the drawings.

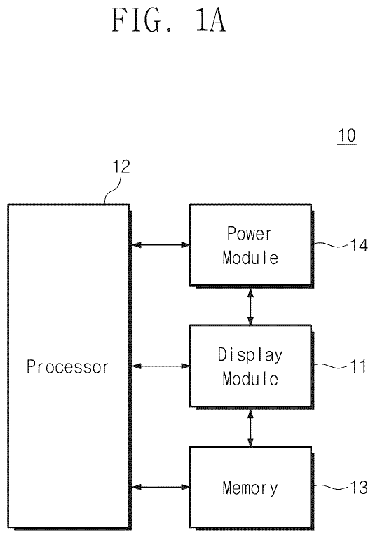

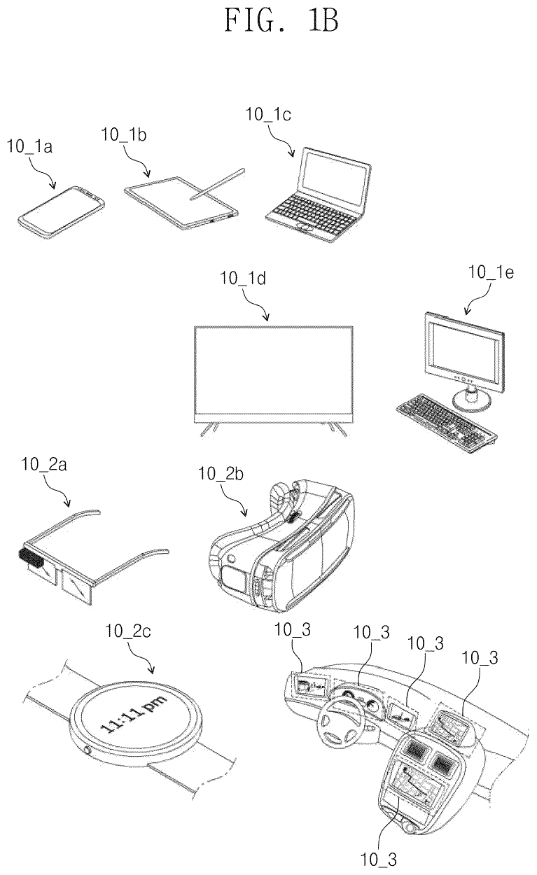

FIG. 1A is a block diagram of an electronic device according to an embodiment. FIG. 1B is a schematic view of electronic devices according to various embodiments.

Referring to FIG. 1A, an electronic device 10 according to an embodiment may include a display module 11, a processor 12, a memory 13 and a power module 14.

The processor 12 may include at least one among a central processing unit (CPU), an application processor (AP), a graphic processing unit (GPU), a communication processor (CP), an image signal processor (ISP) and a controller.

Data information required for an operation of the processor 12 or the display module 11 may be stored in the memory 13. When the processor 12 executes an application stored in the memory 13, an image data signal and/or an input control signal may be transferred to the display module 11, and the display module 11 may process the provided signal and output image information through a display screen.

The power module 14 may include a power supply module such as a power adaptor or a battery device and a power conversion module which converts power supplied by the power supply module and generates power required for an operation of the electronic device 10.

At least one of the components of the electronic device 10 described above may be included in a display device according to the embodiments described above. In addition, some of individual modules functionally included in one module may be included in the display device, and the others thereof may be provided separately from the display device. For example, the display device may include the display module 11, and the processor 12, the memory 13 and the power module 14 may be provided in a form of another device in the electronic device 10, not the display device.

Referring to FIG. 1B, various electronic devices to which a display device according to embodiments is applied may include not only electronic devices for displaying images, such as a smartphone 10_1a, a tablet PC 10_1b, a laptop 10_1c, a television 10_1d and a desk monitor 10_1e but also wearable electronic devices including a display module, such as smart glasses 10_2a, a head-mounted display 10_2b and a smart watch 10_2c, automotive electronic devices 10_3 including a display module, such as a center information display (CID) disposed on an instrument panel, center fascia, and a dashboard of an automobile and a room mirror display, etc.

The display device according to an embodiment may be applied to various electronic devices. The electronic device according to an embodiment may include the display device described above, and may further include another module or device having an additional function in addition to the display device. Hereinafter, an electronic device ED according to an embodiment among the electronic devices described above will be described.

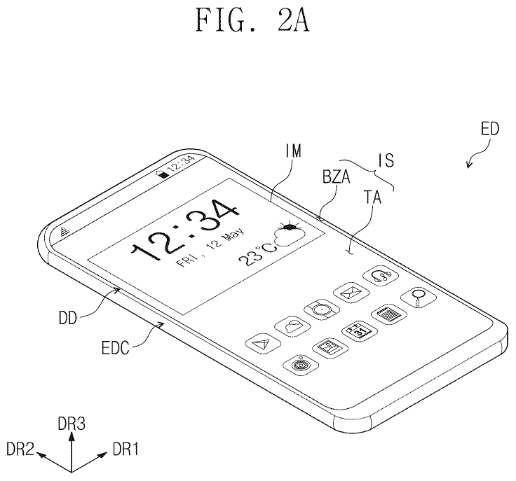

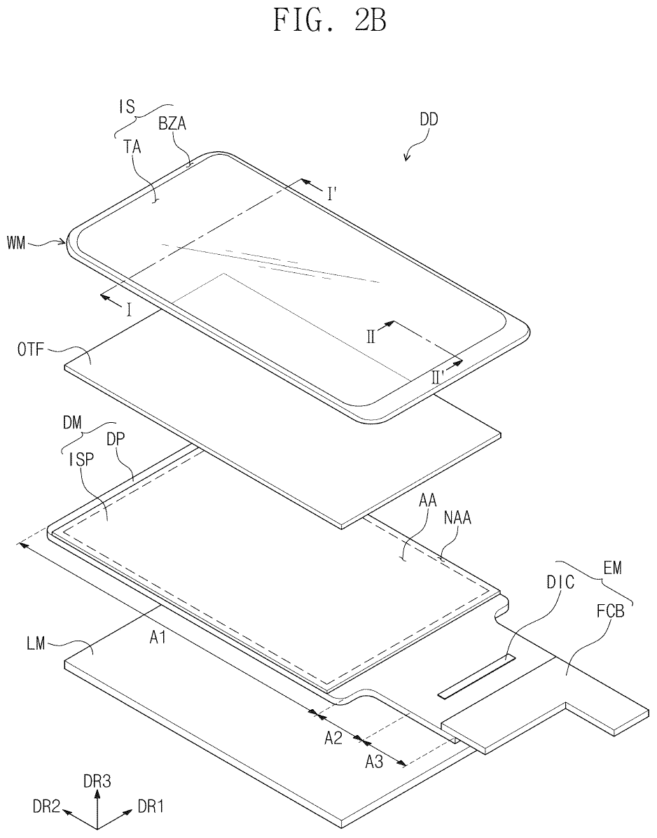

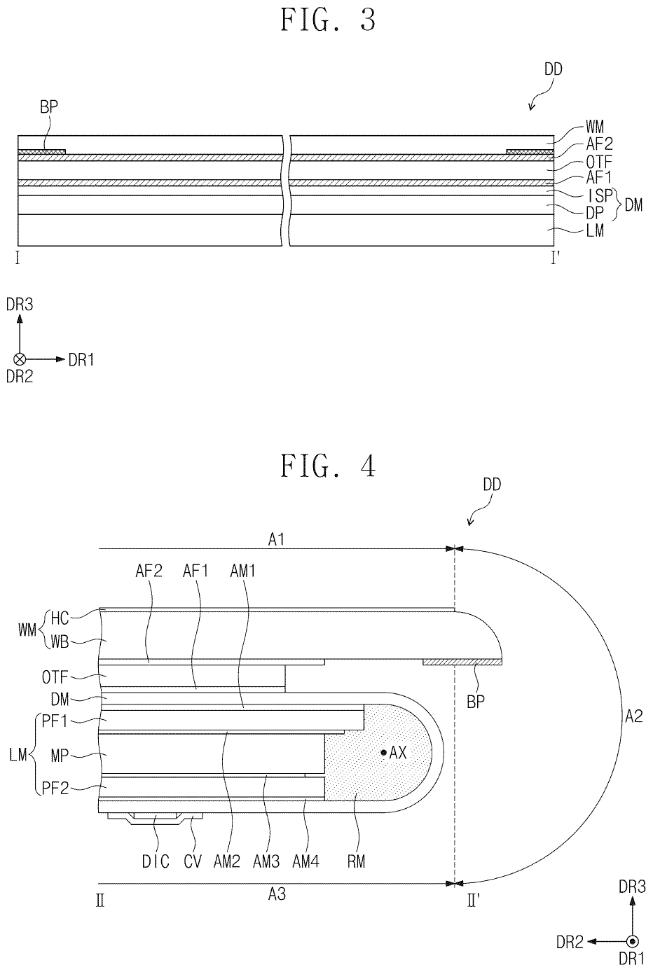

FIG. 2A is a perspective view of an electronic device according to an embodiment of the invention. FIG. 2B is an exploded perspective view of a display device according to an embodiment of the invention. FIG. 3 is a cross-sectional view taken along I-I′ of FIG. 2B. FIG. 4 is a cross-sectional view taken along II-II′ of FIG. 2B in a state in which a region of a display panel is bent.

Referring to FIGS. 2A to 3, the electronic device ED may be activated in response to an electrical signal. The electronic device ED may include various embodiments. For example, the electronic device ED may be a display device such as a smart watch, a tablet PC, a laptop, a computer and a smart television.

The electronic device ED may display an image IM in a third direction DR3 on a display surface IS parallel to each of a first direction DR1 and a second direction DR2. The display surface IS on which the image IM is displayed may correspond to a front surface of the electronic device ED. The image IM may include a static image as well as a dynamic image.

In the present embodiment, a front surface (or an upper surface) and a rear surface (or a lower surface) of each of members are defined with respect to the third direction DR3 in which the image IM is displayed. The front surface and the rear surface may be opposed to each other in the third direction DR3, and a normal direction of each of the front surface and the rear surface may be parallel to the third direction DR3.

A separation distance between the front surface and the rear surface in the third direction DR3 may correspond to a thickness of the electronic device ED in the third direction DR3. Meanwhile, directions indicated by the first to third directions DR1, DR2 and DR3 have relative concepts and may be changed into other directions.

The electronic device ED may sense an external input applied from the outside. The external input may include various types of inputs provided from an outside of the electronic device ED. For example, the external input may include not only a contact from a part of a body such as a user's hand but also an external input (for example, hovering) applied close to the electronic device ED or adjacent to the electronic device ED at a predetermined distance. In addition, the external input may have various forms such as force, pressure, temperature and light.

The display surface IS of the electronic device ED may be divided into a transmission region TA and a bezel region BZA. The transmission region TA may be a region in which the image IM is displayed. A user views the image IM through the transmission region TA. In the present embodiment, the transmission region TA is illustrated in a quadrangular shape having rounded vertices. However, this is illustrated as an example, and the transmission region TA may have various shapes and is not limited to any one embodiment.

The bezel region BZA is adjacent to the transmission region TA. The bezel region BZA may have a predetermined color. The bezel region BZA may surround the transmission region TA in a plan view. Accordingly, a shape of the transmission region TA may be substantially defined by the bezel region BZA. However, this is illustrated as an example, and the bezel region BZA may be disposed adjacent to only one side of the transmission region TA or may be omitted. The electronic device ED according to an embodiment of the invention may include various embodiments and is not limited to any one embodiment.

The electronic device ED may include a display device DD and an external case EDC (a housing). The display device DD may include a window WM, a display module DM, a driving module EM, an optical film OTF and a lower module LM. The display module DM may include a display panel DP and an input sensor ISP disposed on the display panel DP. The display panel DP generates the image IM, and the input sensor ISP acquires coordinate information about an external input (for example, a touch event). The lower module LM may include various functional layers and is illustrated in a plate shape extending along the first direction DR1 and the second direction DR2 in FIG. 2B, but shapes of the functional layers included in the lower module LM may be different thereto.

The window WM may include a transparent material through which an image may be emitted. For example, the window WM may include glass, sapphire, plastic, etc. The window WM is illustrated as a single layer but is not limited thereto and may include a plurality of layers. Meanwhile, although not illustrated, the bezel region BZA of the display device DD described above may be substantially provided as a region of the window WM printed with a material having a predetermined color.

The display module DM may include the display panel DP and the input sensor ISP. The display panel DP according to an embodiment of the invention may be an emissive display panel but is not particularly limited thereto. For example, the display panel DP may be an organic light-emitting display panel, an inorganic light-emitting display panel or a quantum dot light-emitting display panel. An emission layer of the organic light-emitting display panel may include an organic light-emitting material, and an emission layer of the inorganic light-emitting display panel may include an inorganic light-emitting material. An emission layer of the quantum dot light-emitting display panel may include quantum dots, quantum rods, and the like. Hereinafter, the display panel DP is described as an organic light-emitting display panel.

The input sensor ISP may be “directly disposed” on the display panel DP. According to an embodiment of the invention, the input sensor ISP may be formed on the display panel DP through a continuous process. That is, when the input sensor ISP is directly disposed on the display panel DP, an adhesive film for coupling the input sensor ISP and the display panel DP is not disposed between the input sensor ISP and the display panel DP.

The optical film OTF reduces reflectance for external light incident from above the window WM. The optical film OTF according to an embodiment of the invention may include a retarder and a polarizer. The retarder may be a film-type retarder or a liquid crystal coating-type retarder and include ë/2 retarder and/or ë/4 retarder. The polarizer may also be a film-type polarizer or a liquid crystal coating-type polarizer. The film type may include a stretchable synthetic resin film, and the liquid crystal coating type may include liquid crystals arranged in a predetermined arrangement. The retarder and the polarizer may be implemented as one polarizing film. The optical film OTF may further include a protective film disposed above or below the polarizing film.

The optical film OTF may be disposed on the input sensor ISP. That is, the optical film OTF may be disposed between the input sensor ISP and the window WM. The input sensor ISP, the optical film OTF and the window WM may be coupled to each other through an adhesive layer.

Referring to FIG. 3, an optical adhesive layer AF1 is disposed between the input sensor ISP and the optical film OTF, and a window adhesive layer AF2 is disposed between the optical film OTF and the window WM. Thus, the optical film OTF is coupled to the input sensor ISP by the optical adhesive layer AF1, and the window WM is coupled to the optical film OTF by the window adhesive layer AF2.

As an example of the invention, the adhesive layers AF1 and AF2 may each include an optically clear adhesive film (OCA). However, a material of each of the adhesive layers AF1 and AF2 is not limited thereto and may include a typical adhesive or bonding agent. For example, the adhesive layers AF1 and AF2 may each include a pressure sensitive adhesive (PSA), an optical clear adhesive (OCA) or an optical clear resin (OCR).

A functional layer which performs another function, for example, a protective layer, etc., may be further disposed between the display module DM and the window WM in addition to the optical film OTF.

The display module DM may display an image in response to an electrical signal and transmit/receive information about an external input. The display module DM may be defined as an active region AA and a peripheral region NAA. The active region AA may be defined as a region in which an image provided from the display module DM is emitted.

The peripheral region NAA is adjacent to the active region AA. For example, the peripheral region NAA may surround the active region AA in a plan view. However, this is illustrated as an example, and the peripheral region NAA may be defined in various shapes and is not limited to any one embodiment. According to an embodiment, the active region AA of the display module DM may correspond to at least a portion of the transmission region TA.

According to the invention, the display module DM may include a first region A1, a second region A2 and a third region A3 which are arranged along the second direction DR2. The first region A1 may include a portion of the peripheral region NAA and the active region AA, and the second region A2 and the third region A3 may include the rest of the peripheral region NAA. The second region A2 may be a bending region which is bent with respect to an imaginary bending axis extending along the first direction DR1, and the first region A1 and the third region A3 may be a non-bending region.

The third region A3 may be disposed below the first region A1 in a state in which the second region A2 is bent with respect to the bending axis. Accordingly, the driving module EM disposed in the third region A3 may be disposed below the first region A1 in a state in which the second region A2 is bent.

In the first direction DR1, a length of each of the second region A2 and the third region A3 in the first direction DR1 may be smaller than or equal to a length of the first region A1 in the first direction DR1. A region of which a length in a direction of the bending axis is short may be more easily bent.

The driving module EM may control driving of the display module DM. The driving module EM may include a flexible circuit film FCB and a driving chip DIC. The flexible circuit film FCB may be electrically connected to the display panel DP. The flexible circuit film FCB may be coupled to an end of the third region A3 of the display module DM through a bonding process. The flexible circuit film FCB may be electrically connected to the display module DM through an anisotropic conductive adhesive layer. The driving chip DIC may be mounted on the third region A3 of the display module DM. The driving chip DIC may include driving circuits, for example, a data driving circuit, for driving pixels of the display panel DP. According to an embodiment, the flexible circuit film FCB may include a ground line for discharging static electricity introduced to the flexible circuit film FCB or static electricity introduced to the input sensor ISP.

After a process of bending the second region A2, a process of compressing the flexible circuit film FCB may be performed in a state in which the second region A2 is bent. In this case, in a case in which a cushion layer including synthetic resin foam, etc. is included among components included in the lower module LM, elements included in the flexible circuit film FCB may be transferred to the display panel DP during the compressing process, causing degradation of surface quality of the display panel DP.

The driving module EM may further include a plurality of driving elements mounted on the flexible circuit film FCB. The plurality of driving elements may include a circuit part for converting a signal input from the outside into a signal required for the driving chip DIC or a signal required for driving the display module DM.

The lower module LM is disposed on a rear surface of the display module DM. Since the lower module LM is disposed on the rear surface of the display module DM, the lower module LM may improve impact resistance of the display device DD. The lower module LM may be fixed to the rear surface of the display module DM through an adhesive layer.

When the second region A2 and the third region A3 of the display module DM are bent, the third region A3 of the display module DM and the flexible circuit film FCB may be disposed on a rear surface of the lower module LM.

The external case EDC may be coupled to the window WM and define an exterior of the electronic device ED. The external case EDC accommodates the display device DD. The external case EDC protects components accommodated in the external case EDC by absorbing an impact applied from the outside and preventing foreign substances/moisture or the like from being introduced to the electronic device ED. Meanwhile, as an example of the invention, the external case EDC may be provided in a form in which a plurality of accommodation members are coupled to each other.

FIG. 4 illustrates a cross-sectional view of a portion of the display device DD, which is adjacent to the second region A2, in a state in which the second region A2 is bent with respect to a bending axis AX extending along the first direction DR1.

The display device DD may include the window WM, the optical film OTF, the display module DM and the lower module LM. The lower module LM may include a first protective member PF1, a second protective member PF2 and a functional layer MP.

The window WM according to an embodiment may include a base portion WB, a hard coating layer HC and a bezel pattern BP. The base portion WB may include an optically transparent insulating material. For example, the base portion WB may include a glass substrate or a synthetic resin film. The hard coating layer HC for protecting the base portion WB may be disposed on one of a front surface and a rear surface of the base portion WB. The hard coating layer HC may prevent the base portion WB from being damaged by scratches and the like. In addition, an anti-fingerprint layer may be further disposed on the base portion WB.

The bezel pattern BP defines the bezel region BZA (see FIG. 1) of the window WM. The bezel pattern BP may be disposed adjacent to an edge of the rear surface of the base portion WB.

The bezel pattern BP may be a colored layer and formed through coating. The bezel pattern BP may include a polymer resin and a pigment mixed in the polymer resin. The polymer resin may be, for example, an acrylic resin or polyester, and the pigment may be a carbon-based pigment.

The optical film OTF may be disposed below the window WM. The optical film OTF may reduce reflectance for external light incident from the window WM. The window WM and the optical film OTF may be coupled to each other through a window adhesive layer AF2. The display module DM and the optical film OTF may be coupled to each other through an optical adhesive layer AF1.

The lower module LM may be disposed below the display module DM. The lower module LM may include the first protective member PF1, the second protective member PF2 and the functional layer MP.

The display module DM and the first protective member PF1 may be coupled to each other through a first adhesive layer AM1.

The functional layer MP may be disposed below the first protective member PF1. The functional layer MP and the first protective member PF1 may be coupled to each other through a second adhesive layer AM2. The functional layer MP may be provided in a plate shape. The functional layer MP may include a plurality of layers. For example, the functional layer MP may include a light-shielding layer, a heat dissipation layer, a cushion layer and a plurality of adhesive layers.

The light-shielding layer may serve to improve an issue in which components disposed in the display module DM are visible through the window WM via active regions AA. The light-shielding layer may include a binder and a plurality of pigment particles dispersed therein. The pigment particles may include carbon black, etc. The electronic device ED according to an embodiment may have an effect of improving a light shielding property by including the light-shielding layer.

The heat dissipation layer may effectively dissipate heat generated from the display module DM. The heat dissipation layer may include at least one of aluminum (Al), copper (Cu) or graphite having excellent heat dissipation characteristics, but an embodiment of the invention is not limited thereto. The heat dissipation layer may not only improve heat dissipation characteristics but also have electromagnetic wave shielding or electromagnetic wave absorbing characteristics.

The cushion layer may be synthetic resin foam. The cushion layer may include a matrix and a plurality of pores. The cushion layer may have elasticity and a porous structure.

The matrix may include a flexible material. The matrix includes a synthetic resin. For example, the matrix may include at least one of acrylonitrile butadiene styrene copolymer (ABS), polyurethane (PU), polyethylene (PE), ethylene vinyl acetate (EVA) or polyvinyl chloride (PVC). The plurality of pores easily absorb an impact applied to the cushion layer. The plurality of pores may be defined since the cushion layer has a porous structure.

According to an embodiment, at least one of the light-shielding layer, the heat dissipation layer or the cushion layer included in the functional layer MP may be omitted, and a plurality of layers may be provided as a single layer, but the functional layer MP is not limited to any one embodiment.

The functional layer MP and the second protective member PF2 may be coupled to each other through a third adhesive layer AM3. The second protective member PF2 may be disposed on a rear surface of the display module DM overlapping the second region A2. The display module DM and the second protective member PF2 may be coupled to each other through a fourth adhesive layer AM4 in a state in which the second region A2 is bent.

The first to fourth adhesive layers AM1, AM2, AM3 and AM4 may each include an optically clear adhesive film (OCA). However, a material of each of the first to fourth adhesive layers AM1, AM2, AM3 and AM4 is not limited thereto and may include a typical adhesive or bonding agent. For example, the first to fourth adhesive layers AM1, AM2, AM3 and AM4 may each include a pressure sensitive adhesive (PSA), an optical clear adhesive (OCA), or an optical clear resin (OCR).

The electronic device ED according to an embodiment may include a protective layer RM. The protective layer RM may be disposed in an inner space defined by the rear surface of the display module DM overlapping the second region A2 when the display module DM is bent, a side surface of the first protective member PF1, a side surface of the functional layer MP, a side surface of the second protective member PF2 and a side surface of each of the first to fourth adhesive layers AM1, AM2, AM3 and AM4.

Since the protective layer RM is disposed in the inner space, the protective layer RM may support the display module DM when the display module DM is bent so that a shape of the second region A2 may be maintained. In addition, the protective layer RM may prevent foreign substances, etc. from being introduced into the display module DM through the second region A2. The protective layer RM according to an embodiment may include a resin.

The display panel DP according to an embodiment may further include a bending cover layer BCV disposed on the second region A2. The bending cover layer BCV may reduce stress applied to the second region A2 when the second region A2 is bent and may protect the second region A2.

The display device DD according to an embodiment may further include a conductive film CV disposed in the third region A3. The conductive film CV may prevent static electricity introduced from the outside from damaging the driving chip DIC and prevent foreign substances, etc. from being introduced into the driving chip DIC by covering the driving chip DIC. In addition, the conductive film CV may prevent an impact from being applied to the driving chip DIC.

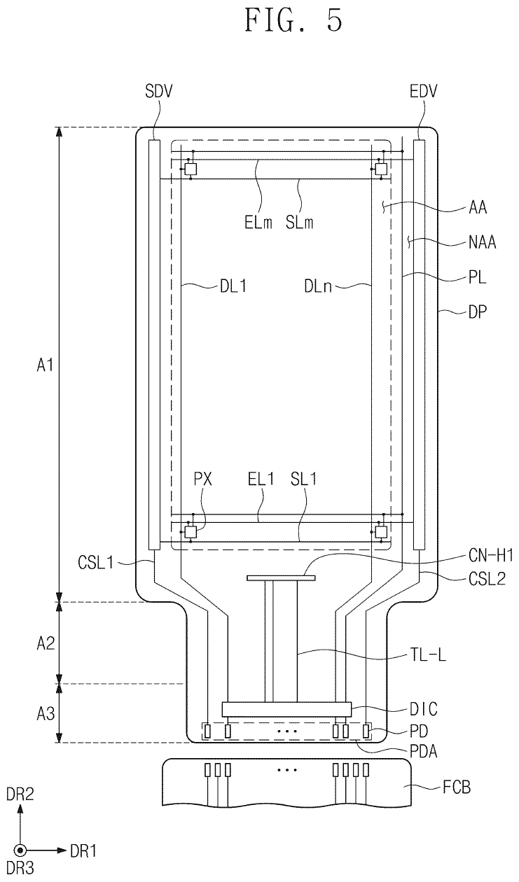

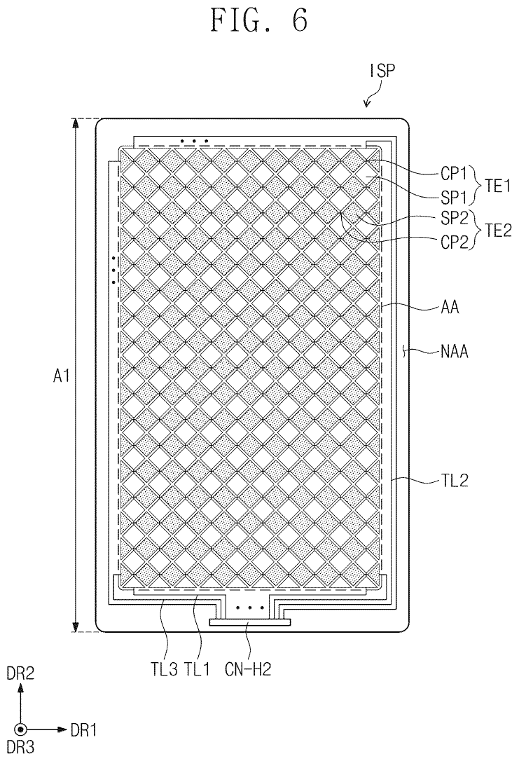

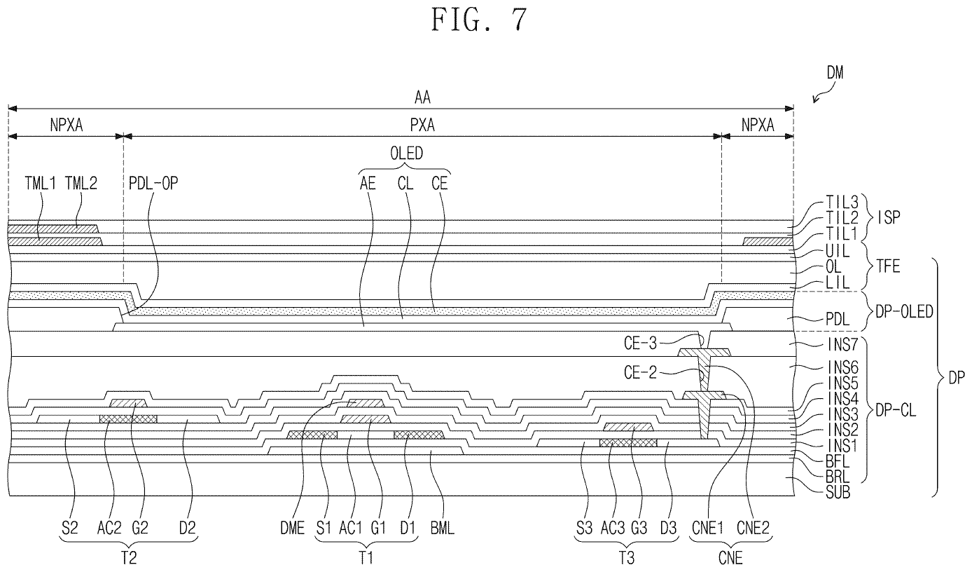

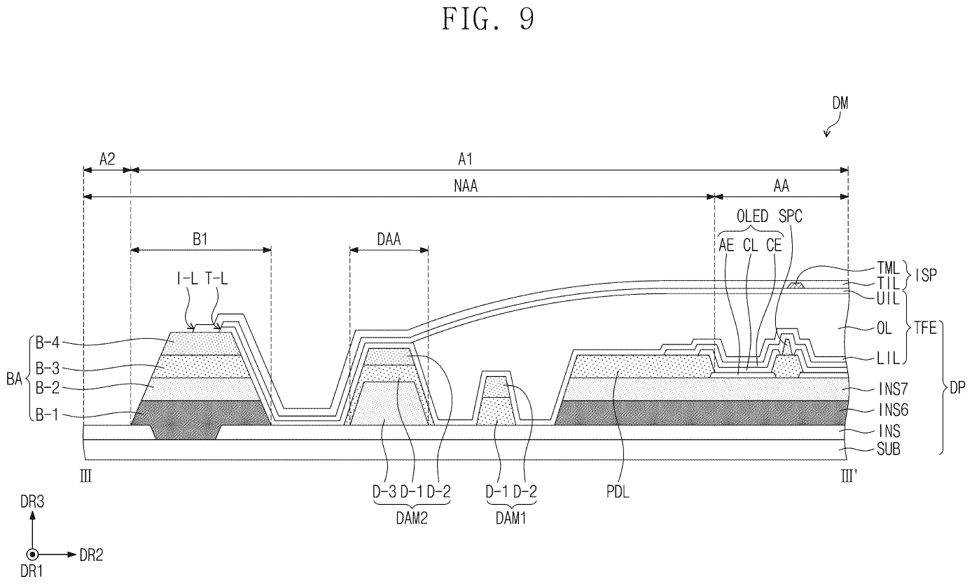

FIG. 5 is a plan view of a display panel according to an embodiment of the invention. FIG. 6 is a plan view of an input sensor according to an embodiment of the invention. FIG. 7 is a cross-sectional view of a display module according to an embodiment of the invention. As used herein, the “plan view” is a view in a thickness direction (i.e., third direction DR3) of the electronic device or a base layer SUB (See FIG. 9).

A display panel DP according to an embodiment of the invention may be divided into a first region A1, a second region A2 and a third region A3 which are arranged along the second direction DR2. The first to third regions A1, A2 and A3 of the display panel DP illustrated in FIG. 5 respectively correspond to the first to third regions A1, A2 and A3 of the display module DM described with reference to FIG. 2. As used herein, the wording “a region/portion corresponds to a region/portion” means that a region/portion overlaps a region/portion and is not limited to meaning that regions/portions have the same area.

The display panel DP according to an embodiment may include an active region AA in which a pixel PX is disposed and a peripheral region NAA adjacent to the active region AA. The active region AA and the peripheral region NAA respectively correspond to the active region AA and the peripheral region NAA described with reference to FIG. 2. The active region AA corresponds to a region, in which the pixel PX is disposed, of the first region A1, and the peripheral region NAA is defined as the remaining region except for the region in which the pixel PX is disposed.

The first region A1 may include a portion of the peripheral region NAA and the active region AA, and the second region A2 and the third region A3 may include the remaining portion of the peripheral region NAA.

The display panel DP may include a scan driver SDV, an emission driver EDV, pads PD and a driving chip DIC in the peripheral region NAA. In the present embodiment, the driving chip DIC may be a data driver.

The display panel DP may include a plurality of pixels PX, a plurality of scan lines SL1 to SLm, a plurality of data lines DL1 to DLn, a plurality of emission lines EL1 to ELm, first and second control lines CSL1 and CSL2, a power line PL and a plurality of pads PD. Here, m and n are natural numbers. The pixels PX may be connected to the scan lines SL1 to SLm, the data lines DL1 to DLn and the emission lines EL1 to ELm.

The scan lines SL1 to SLm may extend in the first direction DR1 and may be connected to the scan driver SDV. The data lines DL1 to DLn may extend in the second direction DR2 and may be connected from the first region A1 to the driving chip DIC disposed in the third region A3 via the second region A2. The emission lines EL1 to ELm may extend in the first direction DR1 and may be connected to the emission driver EDV.

The power line PL may include a portion extending in the first direction DR1 and a portion extending in the second direction DR2 (not shown). The portion extending in the first direction DR1 and the portion extending in the second direction DR2 may be disposed at different layers. The portion of the power line PL, extending in the second direction DR2, may extend from the first region A1 to the third region A3 via the second region A2. The power line PL may provide a reference volage to the pixels PX.

The first control line CSL1 may be connected to the scan driver SDV and extend from the first region A1 to the third region A3 via the second region A2. The second control line CSL2 may be connected to the emission driver EDV and extend from the first region A1 to the third region A3 via the second region A2.

The pads PD may be disposed adjacent to an end of the third region A3. The driving chip DIC, the power line PL, the first control line CSL1 and the second control line CSL2 may be connected to the pads PD. A flexible circuit film FCB may be disposed on the display panel DP while overlapping the end of the third region A3 of the display panel DP. The flexible circuit film FCB may include pads corresponding to the pads PD and may be electrically connected to the pads PD through an anisotropic conductive film (ACF).

The display panel DP according to an embodiment may include a first contact hole CN-H1 defined in the peripheral region NAA of the first region A1 and extension trace lines TL-L. The extension trace lines TL-L may extend to the third region A3 via the first region A1 and the second region A2. The extension trace lines TL-L may be connected, in one-to-one manner, to corresponding trace lines among trace lines TL1, TL2 and TL3 (see FIG. 6) to be described later through the first contact hole CN-H1. For example, one end of each of the extension trace lines TL-L may be exposed from the first contact hole CN-H1 and connected to the trace lines TL1, TL2 and TL3 (see FIG. 6), and the other end of each of the extension trace lines TL-L may be connected to the pads PD.

In a structure of the display panel DP in which a region is bent as in the invention, layers including an organic material among insulating layers disposed in the display panel DP may not be disposed in the second region and may be disconnected in the first region A1.

Moisture/oxygen may permeate into the display panel DP through insulating layers including an organic material in the first region A1 adjacent to the second region A2.

Referring to FIG. 6, an input sensor ISP according to an embodiment may include sensing electrodes TE1 and TE2 and trace lines TL1, TL2 and TL3. When the input sensor ISP is directly formed on the display panel DP through a continuous process, the sensing electrodes TE1 and TE2 may be formed only in an active region AA overlapping the first region A1 of the display panel DP.

The input sensor ISP may acquire information about an external input through a change in capacitance between first sensing electrodes TE1 and second sensing electrodes TE2. The first sensing electrodes TE1 are arranged along the first direction DR1 and each extend along the second direction DR2. The first sensing electrodes TE1 may each include first sensing patterns SP1 and first connection patterns CP1.

The first sensing patterns SP1 are disposed in the active region AA. The first sensing patterns SP1 included in one first sensing electrode TE1 may be arranged along the second direction DR2. The first sensing patterns SP1 may have a rhombic shape. However, this is illustrated as an example, and the first sensing patterns SP1 may have various shapes and are not limited to any one embodiment.

The first connection pattern CP1 is disposed in the active region AA. The first connection pattern CP1 may be disposed between adjacent first sensing patterns SP1. The first connection pattern CP1 may be disposed at a layer different from a layer at which the first sensing pattern SP1 is disposed, and connected to the first sensing pattern SP1 through a contact hole.

The second sensing electrodes TE2 are arranged along the second direction DR2 and each extend along the first direction DR1. The second sensing electrodes TE2 may each include second sensing patterns SP2 and second connection patterns CP2.

The second sensing patterns SP2 may be spaced apart from the first sensing patterns SP1. The first sensing patterns SP1 and the second sensing patterns SP2 may transmit and receive independent electrical signals without being in contact with each other.

The second sensing patterns SP2 are disposed in the active region AA. The second sensing patterns SP2 included in one second sensing electrode TE2 may be arranged along the first direction DR1. The second sensing patterns SP2 may have the same shape as the first sensing pattern SP1. For example, the second sensing patterns SP2 may have a rhombic shape. However, this is illustrated as an example, and the second sensing patterns SP2 may have various shapes and are not limited to any one embodiment.

The second connection pattern CP2 may be disposed between adjacent second sensing patterns SP2. Substantially, the second sensing patterns SP2 and the second connection patterns CP2 included in one second sensing electrode TE2 may be formed in an integrated shape or as an integrated pattern.

According to an embodiment, the first sensing patterns SP1, the second sensing patterns SP2 and the second connection patterns CP2 may be disposed at a same layer, and the first sensing patterns SP1 may be disposed at a different layer. The first sensing patterns SP1, the second sensing patterns SP2 and the second connection patterns CP2 may be provided as a plurality of mesh lines extending in a diagonal direction of each of the first direction DR1 and the second direction DR2.

The trace lines TL1, TL2 and TL3 are disposed in a peripheral region NAA. The trace lines TL1, TL2 and TL3 may include first trace lines TL1, second trace lines TL2 and third trace lines TL3.

One end of each of the first trace lines TL1 are respectively connected to the first sensing electrodes TE1. In the present embodiment, the first trace lines TL1 are respectively connected to lower ends among both ends of each of the first sensing electrodes TE1. One end of each of the second trace lines TL2 are respectively connected to upper ends among the both ends of each of the first sensing electrodes TE1. According to the invention, the first sensing electrodes TE1 may be connected to each of the first trace lines TL1 and the second trace lines TL2. Accordingly, the first sensing electrodes TE1 having a relatively great length compared to the second sensing electrodes TE2 may be able to uniformly maintain region-dependent sensitivity.

Meanwhile, this is illustrated as an example, and in the input sensor ISP according to an embodiment of the invention, any one of the first trace lines TL1 and the second trace lines TL2 may be omitted, and the input sensor ISP is not limited to any one embodiment.

One end of each of the third trace lines TL3 are respectively connected to one end of each of the second sensing electrodes. In the present embodiment, the third trace lines TL3 are respectively connected to left ends among both ends of each of the second sensing electrodes TE2.

A second contact hole CN-H2, which is defined by penetrating at least one of insulating layers included in the input sensor ISP, may be defined in the input sensor ISP. The second contact hole CN-H2 may overlap the first contact hole CN-H1 defined in the peripheral region NAA of the display panel DP in a plan view.

The other end of each of the trace lines TL1, TL2 and TL3 may be disposed in the second contact hole CN-H2. The other end of each of the trace lines TL1, TL2 and TL3, which are disposed in the second contact hole CN-H2, may be connected to the extension trace lines TL-L (see FIG. 5). The trace lines TL1, TL2 and TL3 may be connected to the pads PD (see FIG. 5) through the extension trace lines TL-L disposed in the display panel DP (see FIG. 5).

FIG. 7 is a cross-sectional view of one pixel PX disposed in a display panel DP. Referring to FIG. 7, a light-emitting element OLED according to an embodiment may include a first electrode AE, a second electrode CE and a common layer CL. The common layer CL may include a hole control layer, an electron control layer, an emission layer, and the like.

The second electrode CE may be disposed on the first electrode AE, and the common layer CL may be disposed between the first electrode AE and the second electrode CE. The light-emitting element OLED according to an embodiment may further include a protective layer disposed on the second electrode CE. The protective layer may include an organic material and prevent components disposed below the protective layer from being damaged in a subsequent process. According to an embodiment, the protective layer may be omitted.

A second driving voltage ELVDD provided from the power line PL may be applied to the first electrode AE, and a first driving voltage ELVSS having a lower level than the second driving voltage ELVDD may be applied to the second electrode CE. Holes and electrons injected to the common layer CL may combine to form excitons, and as the excitons transition to a ground state, the light-emitting element OLED may emit light. The light-emitting element OLED may emit light, and thus an image may be displayed.

FIG. 7 illustrates three first to third transistors T1, T2 and T3 included in the pixel PX as an example, and the number and type of transistors and the number and type of capacitors included in one pixel PX are not limited to any one embodiment.

The first, second and third transistors T1, T2 and T3 and the light-emitting element OLED may be disposed on a base layer SUB. An active region AA may include a light-emitting region PXA and a non-light-emitting region NPXA adjacent to the light-emitting region PXA. The first, second and third transistors T1, T2 and T3 may include semiconductor layers including channel regions AC1, AC2 and AC3, source regions S1, S2 and S3 and drain regions D1, D2 and D3, and gate electrodes G1, G2 and G3 disposed on the semiconductor layers, respectively.

The base layer SUB may include glass or a flexible plastic material such as polyimide (PI). A circuit element layer DP-CL, a display element layer DP-OLED and a thin-film encapsulation layer TFE may be disposed on the base layer SUB. The circuit element layer DP-CL may be disposed on the base layer SUB. The circuit element layer DP-CL may include insulating layers and conductive patterns. The display element layer DP-OLED may include the light-emitting element OLED and a pixel-defining film PDL.

A barrier layer BRL may be disposed on the base layer SUB. The barrier layer BRL may increase bonding force between the base layer SUB and the semiconductor layers included in the transistors. The barrier layer BRL may include an inorganic material.

A metal layer BML may be disposed on the barrier layer BRL. The metal layer BML may overlap the first transistor T1 in a plan view. According to an embodiment, a constant voltage may be applied to the metal layer BML. When the constant voltage is applied to the metal layer BML, a value of a threshold voltage Vth of the first transistor T1 disposed on the metal layer BML may be maintained without being changed.

The metal layer BML may block light incident on the first transistor T1 from below the metal layer BML. The metal layer BML may include reflective metal. According to an embodiment, the metal layer BML may be omitted.

A buffer layer BFL may be disposed on the barrier layer BRL and cover the metal layer BML. The buffer layer BFL may include an inorganic material.

The semiconductor layer S1, AC1 and D1 of the first transistor T1 and the semiconductor layer S3, AC3 and D3 of the third transistor T3 may be disposed on the buffer layer BFL. The semiconductor layers S1, AC1, D1, S3, AC3 and D3 may include polysilicon. However, an embodiment of the invention is not limited thereto, and the semiconductor layers S1, AC1, D1, S3, AC3 and D3 may include amorphous silicon.

The semiconductor layers S1, AC1, D1, S3, AC3 and D3 may be doped with an N-type dopant or a P-type dopant. The semiconductor layers S1, AC1, D1, S3, AC3 and D3 may include a heavily doped region and a lightly doped region. The heavily doped region may have higher conductivity than the lightly doped region and substantially serve as a source electrode and a drain electrode of the first and third transistors T1 and T3. The lightly doped region may substantially correspond to an active (or a channel) of the first and third transistors T1 and T3.

A first source region S1, a first channel region AC1 and a first drain region D1 of the first transistor T1 may be formed from the semiconductor layer S1, AC1 and D1. A third source region S3, a third channel region AC3 and a third drain region D3 of the third transistor T3 may be formed from the semiconductor layer S3, AC3 and D3. The first channel region AC1 may be disposed between the first source region S1 and the first drain region D1. The third channel region AC3 may be disposed between the third source region S3 and the third drain region D3.

A first insulating layer INS1 may be disposed on the buffer layer BFL to cover the semiconductor layers S1, AC1, D1, S3, AC3 and D3. A first gate electrode G1 (or a control electrode) of the first transistor T1 and a third gate electrode G3 (or a control electrode) of the third transistor T3 may be disposed on the first insulating layer INS1. In a plan view, the first gate electrode G1 may overlap the first channel region AC1, and the third gate electrode G3 may overlap the third channel region AC3 in a plan view.

A second insulating layer INS2 may be disposed on the first insulating layer INS1 to cover the first and third gate electrodes G1 and G3. A dummy electrode DME may be disposed on the second insulating layer INS2. The dummy electrode DME may be disposed on the first gate electrode G1 and overlap the first gate electrode G1 in a plan view. The dummy electrode DME may form a capacitor together with the first gate electrode G1.

A third insulating layer INS3 may be disposed on the second insulating layer INS2 to cover the dummy electrode DME. The semiconductor layer S2, AC2 and D2 of the second transistor T2 may be disposed on the third insulating layer INS3. The semiconductor layer S2, AC2 and D2 may include oxide semiconductor which is formed of metal oxide. The oxide semiconductor may include crystalline or amorphous oxide semiconductor.

The semiconductor layer S2, AC2 and D2 may include a plurality of regions divided according to whether metal oxide is reduced or not. A region in which metal oxide is reduced (hereinafter, a reduced region) may have higher conductivity than a region in which metal oxide is not reduced (hereinafter, a non-reduced region). The reduced region may substantially serve as a source electrode or a drain electrode of the second transistor T2. The non-reduced region may substantially correspond to an active (or a channel) of the second transistor T2.

A second source region S2, a second channel region AC2 and a second drain region D2 of the second transistor T2 may be formed from the semiconductor layer S2, AC2 and D2. The second channel region AC2 may be disposed between the second source region S2 and the second drain region D2.

A fourth insulating layer INS4 may be disposed on the third insulating layer INS3 to cover the semiconductor layer S2, AC2 and D2. A second gate electrode G2 of the second transistor T2 may be disposed on the fourth insulating layer INS4. In a plan view, the second gate electrode G2 may overlap the second channel region AC2 in a plan view.

A fifth insulating layer INS5 may be disposed on the fourth insulating layer INS4 to cover the second gate electrode G2.

The barrier layer BRL, the buffer layer BFL, and the first to fifth insulating layers INS1 to INS5 may include an inorganic material. By way of example, the barrier layer BRL, the buffer layer BFL, and the first to fifth insulating layers INS1 to INS5 may include one of silicon oxide and silicon nitride, or one insulating layer may include multilayered inorganic layers, and the barrier layer BRL, the buffer layer BFL, and the first to fifth insulating layers INS1 to INS5 are not limited to any one embodiment. The multilayered inorganic layers may have a structure in which layers including silicon nitride and silicon oxide are alternately stacked. Hereinafter, the barrier layer BRL, the buffer layer BFL and the first to fifth insulating layers INS1 to INS5 may be referred to as an inorganic insulating layer INS. At least one among the barrier layer BRL, the buffer layer BFL and the first to fifth insulating layers INS1 to INS5 may be omitted from the inorganic insulating layer INS, and the inorganic insulating layer INS is not limited to any one embodiment.

A connection electrode CNE may be disposed between the third transistor T3 and the light-emitting element OLED. The connection electrode CNE may electrically connect the third transistor T3 and the light-emitting element OLED. The connection electrode CNE may include a first connection electrode CNE1 and a second connection electrode CNE2 disposed on the first connection electrode CNE1.

The first connection electrode CNE1 may be disposed on the fifth insulating layer INS5 and connected to the third drain region D3 through a first contact hole CH1 defined in the first to fifth insulating layers INS1 to INS5. A sixth insulating layer INS6 may be disposed on the fifth insulating layer INS5 to cover the first connection electrode CNE1.

The second connection electrode CNE2 may be disposed on the sixth insulating layer INS6. The second connection electrode CNE2 may be connected to the first connection electrode CNE1 through a second contact hole CH2 defined in the sixth insulating layer INS6.

A seventh insulating layer INS7 may be disposed on the sixth insulating layer INS6 to cover the second connection electrode CNE2. The sixth and seventh insulating layers INS6 and INS7 may include an organic material.

The pixel-defining film PDL may be disposed on the seventh insulating layer INS7. An opening PDL-OP exposing at least a portion of the first electrode AE may be defined in the pixel-defining film PDL. In the present embodiment, the pixel-defining film PDL may include an organic material. In addition, the pixel-defining film PDL may have a predetermined color and is not limited to any one embodiment.

The common layer CL and the second electrode CE included in the light-emitting element OLED may be disposed on the pixel-defining film PDL.

The thin-film encapsulation layer TFE may be disposed on the light-emitting element OLED and cover the light-emitting element OLED. The thin-film encapsulation layer TFE may include a first inorganic layer LIL, an organic layer OL and a second inorganic layer UIL which are sequentially stacked. The first and second inorganic layers LIL and UIL may include an inorganic material and protect the pixels from moisture/oxygen. The organic layer OL may include an organic material and protect the pixels PX from foreign substances such as dust particles.

An input sensor ISP may be directly disposed on the display panel DP. The input sensor ISP may include sensing insulating layers TIL1, TIL2 and TIL3 and one or more conductive layers TML1 and TML2. The sensing insulating layers TIL1, TIL2 and TIL3 may include one of an inorganic material and an organic material.

A first sensing insulating layer TIL1 may be directly disposed on the second inorganic layer UIL of the encapsulation layer TFE. A first conductive layer TML1 is disposed on the first sensing insulating layer TIL1. A second sensing insulating layer TIL2 may be disposed on the first sensing insulating layer TIL1 and cover the first conductive layer TML1. A second conductive layer TML2 is disposed on the second sensing insulating layer TIL2. A third sensing insulating layer TIL3 may be disposed on the second sensing insulating layer TIL2 and cover the second conductive layer TML2. However, an embodiment of the invention is not limited thereto. The first sensing insulating layer TIL1 may be omitted, and the first conductive layer TML1 may be directly disposed on the second inorganic layer UIL, and is not limited to any one embodiment.

According to the invention, the first and second sensing insulating layers TIL1 and TIL2 may include an inorganic material, and the third sensing insulating layer TIL3 may include an organic material. For example, the first and second sensing insulating layers TIL1 and TIL2 may include one of silicon oxide and silicon nitride, or one insulating layer may include multilayered inorganic layers, and the sensing insulating layers TIL1, TIL2 and TIL3 are not limited to any one embodiment.

The first connection patterns CP1 of the sensing electrodes TE1 and TE2 described with reference to FIG. 6 may be included in the first conductive layer TML1. The first sensing patterns SP1, the second sensing patterns SP2 and the second connection patterns CP2 may be included in the second conductive layer TML2. Thus, adjacent first sensing patterns SP1 may be connected to the first connection pattern CP1 through a contact hole defined in the second sensing insulating layer TIL2.

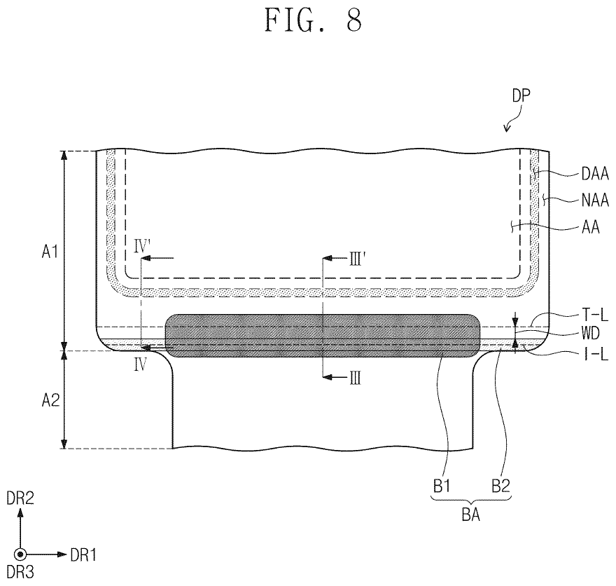

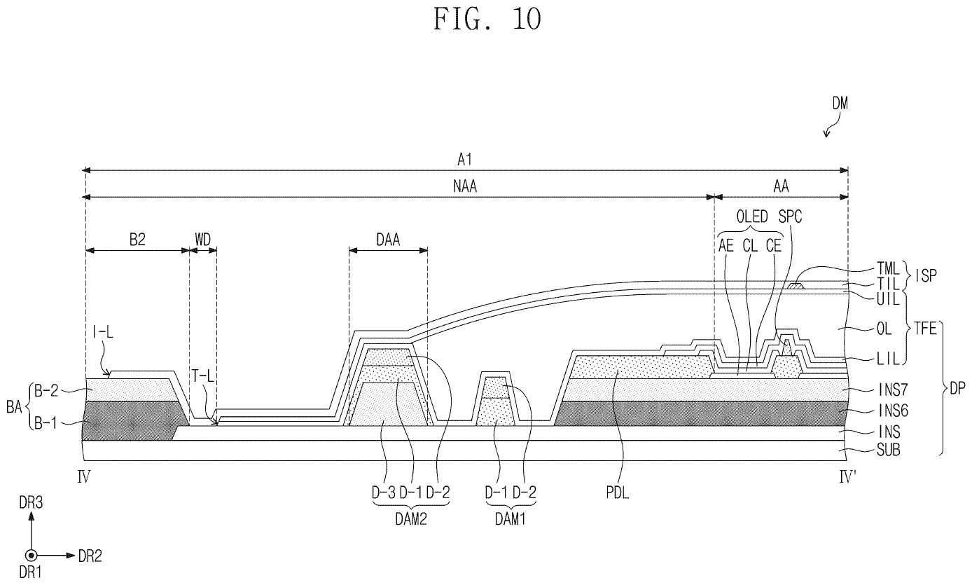

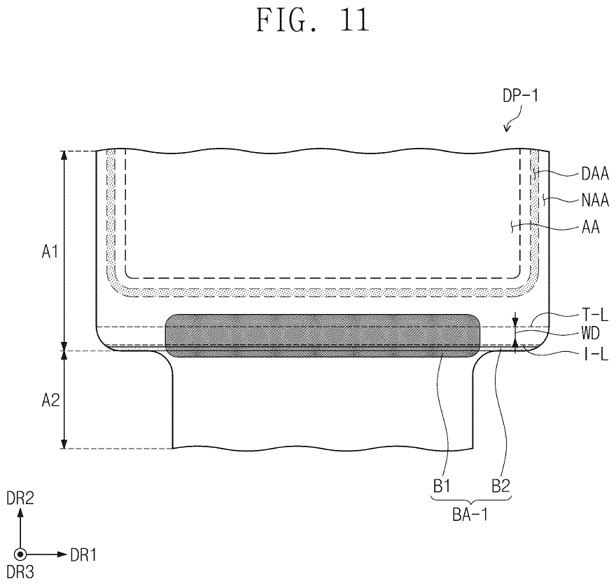

FIG. 8 is a plan view of a region of a display panel according to an embodiment of the invention. FIG. 9 is a cross-sectional view taken along III-III′ of FIG. 8. FIG. 10 is a cross-sectional view taken along IV-IV′ of FIG. 8. Duplicate descriptions of components that are the same as or similar to the components described with reference to FIGS. 5 to 7 are omitted.

In FIG. 8, a portion at which an end of each of the first and second inorganic layers LIL and UIL of the encapsulation layer TFE described with reference to FIG. 7 is disposed is marked by a first line T-L, and a portion at which an end of each of the first and second sensing insulating layers TIL1 and TIL2 of the input sensor ISP is disposed is marked by a second line I-L. The first and second inorganic layers LIL and UIL and the first and second sensing insulating layers TIL1 and TIL2 may include an inorganic material. The first and second sensing insulating layers TIL1 and TIL2 may include an inorganic film which is more robust against permeation of moisture/oxygen than the first and second inorganic layers LIL and UIL.

Referring to FIG. 8, a display panel DP according to the invention may include a bank BA disposed in a first region A1 adjacent to a boundary of a second region A2 which is bent. The bank BA may include a first portion B1 and a second portion B2 according to a region in which organic layers included in the bank BA are disposed. As shown in FIG. 8, the second portion B2 is outside and adjacent to the first portion B1 in a plan view.

The first portion B1 may be disposed at a portion extending from the first region A1 to the second region A2, where a width of the portion in the first direction DR1 decreases in the second direction DR2. Thus, the first portion B1 may be relatively centrally disposed compared to the second portion B2. In the second direction DR2, a width of the first portion B1 may be greater than a width of the second portion B2. In the first direction DR1, a width of the first portion B1 may be greater than a width of the second portion B2.

The second portion B2 may be provided in plurality, and the second portions B2 may be spaced apart from each other with the first portion B1 therebetween along the first direction DR1.

The display panel DP according to the invention may include a dam region DAA. The dam region DAA may be defined as a region in which, among dam portions DAM1 and DAM2 (see FIG. 9) disposed in a peripheral region NAA of the display panel DP, an outermost dam portion is disposed. Thus, the dam region DAA may surround an active region AA in a plan view.

The dam region DAA may define a boundary of the organic layer OL in a process of forming the organic layer OL included in the encapsulation layer TFE. Thus, overflowing of an organic material which forms the organic layer OL may be prevented.

FIG. 9 illustrates a cross-sectional view from the active region AA of the first region A1 to the second region A2 via the peripheral region NAA. Hereinafter, an inorganic insulating layer INS illustrated in the drawings may include one among the barrier layer BRL, the buffer layer BFL, and the first to fifth insulating layers INS1 to INS5 described with reference to FIG. 7.

Referring to FIG. 9, first and second dam portions DAM1 and DAM2 may be disposed in the peripheral region NAA of the first region A1 of the display panel DP. The first and second dam portions DAM1 and DAM2 may be disposed on the inorganic insulating layer INS.

The first dam portion DAM1 may surround the active region AA in a plan view, and the second dam portion DAM2 may surround the first dam portion DAM1 in a plan view. Thus, the dam region DAA defined in FIG. 8 may be defined as a region in which the second dam portion DAM2 is disposed. The second dam portion DAM2 may define a boundary of the organic layer OL included in the encapsulation layer TFE in the peripheral region NAA.

The first dam portion DAM1 may include a first dam pattern D-1 and second dam pattern D-2 which are sequentially stacked. The second dam portion DAM2 may include a first dam pattern D-1, a second dam pattern D-2 disposed on the first dam pattern D-1, and a third dam pattern D-3 disposed under the first dam pattern D-1. The patterns included in the first and second dam portions DAM1 and DAM2 may include an organic material. The first dam pattern D-1 may include the same material as a material of a pixel-defining film PDL. The second dam pattern D-2 may include the same material as a material of a spacer SPC.

The spacer SPC may be an organic film disposed on the pixel-defining film PDL in the active region AA. The spacer SPC may be a component that supports a mask used in a deposition process of forming a common layer CL.

The third pattern D-3 of the second dam portion DAM2 may include the same material as a material of a seventh insulating layer INS7.

Side surfaces and an upper surface of each of the first and second dam portions DAM1 and DAM2 may be covered with the first inorganic layer LIL. The first inorganic layer LIL and the second inorganic layer UIL may be in contact with each other at one side surface and the upper surface of the second dam portion DAM2.

FIG. 9 illustrates a region in which the first portion B1 of the bank BA is disposed. FIG. 10 illustrates a region in which the second portion B2 of the bank BA is disposed. The first portion B1 of the bank BA may be disposed further away from the active region AA than the second dam portion DAM2.

The first portion B1 of the bank BA may include a first pattern B-1, a second pattern B-2, a third pattern B-3 and a fourth pattern B-4 which are sequentially stacked. The first pattern B-1 may be disposed in an opening defined in the inorganic insulating layer INS and in contact with a base layer SUB. Thus, a contact area between the bank BA and the base layer SUB may be increased. Accordingly, even when the second region A2 is bent, the bank BA may be stably attached on the base layer SUB.

The first to fourth patterns B-1, B-2, B-3 and B-4 may each include an organic material. The first pattern B-1 may include the same material as a material of a sixth insulating layer INS6. The second pattern B-2 may include the same material as a material of the seventh insulating layer INS7. The third pattern B-3 may include the same material as a material of the pixel-defining film PDL. The fourth pattern B-4 may include the same material as a material of the spacer SPC.

As illustrated in FIG. 10, the second portion B2 of the bank BA may b disposed further away from the active region AA than the second dam portion DAM2.

The second portion B2 may have a smaller height than the first portion B1 in the third direction DR3. The third and fourth patterns B-3 and B-4 may be omitted from the second portion B2 compared to the first portion B1. Only first and second patterns B-1 and B-2 may be disposed in the second portion B2.

Since the second portion B2 has a smaller height than the first portion B1, the amount of permeation of moisture/oxygen may be relatively large compared to the first portion B1. Thus, in a case in which a lifting phenomenon occurs between the second portion B2 and the dam region DAA, thicknesses of the first and second inorganic layers LIL and UIL which are formed between the second portion B2 and the dam region DAA may be decreased, and this may lead to permeation of moisture/oxygen into the active region AA.

The first pattern B-1 disposed in the first portion B1 and the first pattern B-1 disposed in the second portion B2 may be patterned through the same process and connected to each other. The second pattern B-2 disposed in the first portion B1 and the second pattern B-2 disposed in the second portion B2 may be patterned through the same process and connected to each other.

In FIGS. 9 and 10, the first and second sensing insulating layers TIL1 and TIL2 described with reference to FIG. 7 are illustrated as one sensing insulating layer TIL. In addition, the first and second conductive layers TML1 and TML2 are illustrated as one conductive layer TML. The sensing insulating layer TIL may include only layers including an inorganic material among insulating layers included in the input sensor ISP.

According to the invention, the first line T-L which is the portion at which the end of each of the first and second inorganic layers LIL and UIL of the encapsulation layer TFE is disposed, may overlap the first portion B1 in a plan view and may be spaced apart from the second portion B2.

A portion of an upper surface and one side surface of the first portion B1 may be in contact with the first inorganic layer LIL. Another portion, which is exposed from the first and second inorganic layers LIL and UIL, of the upper surface of the first portion B1 may be in contact with the sensing insulating layer TIL.

A portion of an upper surface and one side surface of the second portion B2 may be in contact with the sensing insulating layer TIL and spaced apart from the first and second inorganic layers LIL and UIL.

When viewed in a region in which the second portion B2 is disposed, the first line T-L may be disposed between the second portion B2 and the dam region DAA and spaced apart from the second portion B2 with a separation space WD therebetween. A width of the separation space WD according to an embodiment in the second direction DR2 may be about 1 μm to about 100 μm.

The second line I-L, which is a portion at which an end of the sensing insulating layer TIL is disposed, may overlap the first portion B1 and the second portion B2 in a plan view.

As illustrated in FIG. 10, in the separation space WD, the sensing insulating layer TIL is in contact with the inorganic insulating layer INS exposed by the first and second inorganic layers LIL and UIL. Accordingly, a permeation path of moisture/oxygen permeating along the second portion B2 may be easily blocked since the first and second inorganic layers LIL and UIL are not in contact with the second portion B2 but are in contact with the inorganic insulating layer INS.

Furthermore, a permeation path of moisture/oxygen may be doubly blocked since the sensing insulating layer TIL, which is more robust against permeation of moisture/oxygen than the first and second inorganic layers LIL and UIL, is in contact with the inorganic insulating layer INS. Accordingly, the electronic device ED with improved reliability and life span may be provided.

FIG. 11 is a plan view of a region of a display panel according to an embodiment of the invention. Components that are the same as or similar to the components described with reference to FIGS. 5 to 10 are denoted as the same or similar reference numerals or symbols, and duplicate descriptions thereof are omitted.

A display panel DP-1 according to an embodiment may include a bank BA-1 disposed in a first region A1 adjacent to a boundary of a second region A2 which is bent. The bank BA-1 may include a first portion B1 and a second portion B2 according to a region in which organic layers included in the bank BA-1 are disposed. The first portion B1 may be defined as a region in which the first to fourth patterns B-1, B-2, B-3 and B-4 described above are disposed, and the second portion B2 may be defined as a region in which only the first and second patterns B-1 and B-2 described above are disposed.

As described above, a first line T-L may overlap only the first portion B1 in a plan view and may be spaced apart from the second portion B2.

According to the present embodiment, a second line I-L may also overlap only the first portion B1 in a plan view and may be spaced apart from the second portion B2. Thus, the second portion B2 may be spaced apart from the first and second inorganic layers LIL and UIL and the sensing insulating layer TIL, and one side surface and an upper surface of the second portion B2 may be exposed from the sensing insulating layer TIL.

According to an embodiment of the invention, a permeation path of moisture/oxygen which permeates along a bank may be easily blocked by adjusting arrangement of the bank and inorganic layers included in an encapsulation layer and inorganic layers included in an input sensor. Accordingly, an electronic device with improved reliability and life span may be provided.

In the above, description has been made with reference to embodiments of the invention, but those skilled or of ordinary skill in the art may understand that various modifications and changes may be made to the invention insofar as such modifications and changes do not depart from the spirit and technical scope of the invention set forth in the claims to be described later.

Therefore, the technical scope of the invention is not to be limited to the contents stated in the detailed description of the specification, but should be determined by the claims.

What is claimed is:

1. An electronic device comprising:
a display panel including an active region and a peripheral region surrounding the active region; and
an input sensor disposed on the display panel and including a sensing insulating layer and sensing electrodes,
wherein the display panel includes a base layer including a first region including the active region, a second region connected to the first region and bent with respect to a bending axis, and a third region connected to the second region and facing the first region,
an inorganic insulating layer disposed on the base layer,
pixels disposed in the active region,
an encapsulation layer including a first inorganic layer covering the pixels, a second inorganic layer disposed on the first inorganic layer, and an organic layer disposed between the first and second inorganic layers,
a dam portion disposed in the peripheral region of the first region and surrounding the active region, and
a bank disposed in the peripheral region of the first region adjacent to a boundary between the first region and the second region and including a first portion and a second portion having a height different from a height of the first portion,
an end of each of the first and second inorganic layers disposed in the peripheral region overlaps the first portion and does not overlap the second portion in a plan view, and
an end of the sensing insulating layer disposed in the peripheral region overlaps the first portion and the second portion in the plan view.

2. The electronic device of claim 1, wherein in the plan view, a width of separation space between the end of each of the first and second inorganic layers and the second portion is about 1 micrometer (μm) to about 100 μm.

3. The electronic device of claim 1, wherein an upper surface of the first portion and one side surface of the first portion facing the dam portion are in contact with the first inorganic layer, and
a portion, which is exposed by the first inorganic layer, of the upper surface is in contact with the sensing insulating layer.

4. The electronic device of claim 1, wherein an upper surface of the second portion and one side surface of the second portion facing the dam portion are in contact with the sensing insulating layer.

5. The electronic device of claim 4, wherein the first and second inorganic layers expose a portion of the inorganic insulating layer adjacent to the one side surface of the second portion, and
the sensing insulating layer is in contact with the portion of the inorganic insulating layer.

6. The electronic device of claim 1, wherein a height of the first portion i greater than a height of the second portion.

7. The electronic device of claim 1, wherein the display panel further comprises a first organic insulating layer disposed on the inorganic insulating layer, a second organic insulating layer disposed on the first organic insulating layer, a pixel-defining film disposed on the second organic insulating layer, and a spacer disposed on the pixel-defining film, and
the first organic insulating layer, the second organic insulating layer, the pixel-defining film and the spacer include an organic material.

8. The electronic device of claim 7, wherein the first portion comprises first to fourth patterns which are sequentially stacked, and
the second portion comprises first and second patterns which are sequentially stacked.

9. The electronic device of claim 8, wherein the first pattern of the first portion comprises a same material as the first organic insulating layer,
the second pattern of the first portion comprises a same material as the second organic insulating layer,
the third pattern of the first portion comprises a same material as the pixel-defining film, and
the fourth pattern of the first portion comprises a same material as the spacer.

10. The electronic device of claim 9, wherein the first pattern of the second portion comprises the same material as the first organic insulating layer, and
the second pattern of the second portion comprises the same material as the second organic insulating layer.

11. The electronic device of claim 10, wherein the first pattern of the first portion and the first pattern of the second portion are provided as one connected pattern, and
the second pattern of the first portion and the second pattern of the second portion are provided as one connected pattern.

12. The electronic device of claim 7, wherein the dam portion comprises a first dam portion surrounding the active region and a second dam portion surrounding the first dam portion.

13. The electronic device of claim 12, wherein the second dam portion defines a boundary of the organic layer in the peripheral region.

14. The electronic device of claim 12, wherein the first dam portion comprises first and second dam patterns which are sequentially stacked, and
the second dam portion comprises first to third dam patterns which are sequentially stacked.

15. The electronic device of claim 14, wherein the first dam pattern of the first dam portion comprises a same material as the pixel-defining film, and
the second dam pattern of the first dam portion comprises a same material as the spacer.

16. The electronic device of claim 14, wherein the second dam pattern of the second dam portion comprises the same material as the pixel-defining film,
the third dam pattern of the second dam portion comprises the same material as the spacer, and
the first dam pattern of the second dam portion comprises a same material as the second organic insulating layer.

17. The electronic device of claim 12, wherein side surfaces and an upper surface of each of the first dam portion and the second dam portion are in contact with the first inorganic layer.

18. The electronic device of claim 1, wherein the inorganic insulating layer comprises insulating layers which are sequentially stacked and include an inorganic material.

19. The electronic device of claim 1, wherein the sensing insulating layer comprises first and second sensing insulating layers which are sequentially stacked and include an inorganic material.

20. The electronic device of claim 1, wherein a width of the second region is smaller than a width of the first region.
